(19) United States
(12) Patent Application Publication
(10) Pub. No.: US 2026/0110896 A1
(43) Pub. Date: Apr. 23, 2026

(54) PROJECTION OBJECTIVE OF A PROJECTION EXPOSURE SYSTEM, AND PROJECTION EXPOSURE SYSTEM

(71) Applicant: Carl Zeiss SMT GmbH, Oberkochen (DE)

(72) Inventors: Jens KUGLER, Aalen (DE); Andreas RABA, Niederschoenefeld (DE); Marwene NEFZI, Aachen (DE)

(21) Appl. No.: 19/427,286

(22) Filed: Dec. 19, 2025

Related U.S. Application Data
(63) Continuation of application No. PCT/EP2024/067967, filed on Jun. 26, 2024.

(30) Foreign Application Priority Data
Jun. 27, 2023 (DE) 10 2023 116 897.5

(51) Int. Cl. G02B 26/08; G03F 7/00

(52) U.S. Cl. CPC G02B 26/0816; G03F 7/70258; G03F 7/70825; G03F 7/709

(57) ABSTRACT

A projection lens comprises an optical module. A semiconductor microlithographic projection exposure apparatus comprises a projection lens comprising such an optical module. The optical module can comprise: an optical element comprising a first segment and a second segment; a stiffening body; a connection element connecting the optical element and the stiffening body; and a lateral decoupling element between the first segment and the stiffening body.

### CROSS-REFERENCE TO RELATED APPLICATIONS

The present application is a continuation of, and claims benefit under 35 USC 120 to, international application No. PCT/EP2024/067967, filed Jun. 26, 2024, which claims benefit under 35 USC 119 of German Application No. 10 2023 116 897.5, filed Jun. 27, 2023. The entire disclosure of each of these applications is incorporated by reference herein.

### FIELD

The disclosure relates to a projection lens of a projection exposure apparatus and to a projection exposure apparatus for semiconductor lithography.

### BACKGROUND

Projection exposure apparatuses for semiconductor lithography are used for producing relatively fine structures, for example on semiconductor components or other microstructured components. The apparatuses can produce relatively fine structures down to the nanometer range by way of generally reducing imaging of structures on a mask, with a so-called reticle, on an element to be structured, such as, for example, a wafer, that is provided with photosensitive material.

In general, minimum dimensions of the structures produced are dependent on the resolution of the optical system of the projection exposure apparatus used for imaging. The resolution, in turn, generally directly depends on the wavelength of the radiation used for imaging, the so-called used radiation and the numerical aperture, i.e. the product of the refractive index of the surrounding medium and the opening angle of the optical system used for imaging.

Light sources that produce radiation in an emission wavelength range referred to as the DUV range from 100 nm to 300 nm and can be used to produce the used radiation. Light sources with an emission wavelength of the order of a few nanometers, for example between 1 nm and 120 nm, such as of the order of 13.5 nm, have found increased use in recent times. The described emission wavelength range is also referred to as the EUV range.

The desired resolution for producing ever smaller structures generally increases from generation to generation, so that, with the emission wavelength remaining the same and a constant refractive index, it can be desirable to increase the opening angle of the optical system.

In general, optical elements such as lens elements and mirrors are used to illuminate the structures and to image them. In the field of EUV lithography, mirrors are typically used on account of the relatively high absorption of the emission wavelengths used therein by most materials. In order to image the structures, so-called optical effective surfaces of the optical elements are exposed to used radiation. The optical effective surfaces and thus the optical elements are also larger on account of the larger opening angle. The larger optical elements involve increased production costs and certain desired properties such as positional stability during imaging and producibility of the optical effective surfaces are affected. Often, these can be produced with conventional production machines and/or processes only with high financial outlay.

### SUMMARY

The present disclosure seeks to provide an improved projection lens including an improved optical module and an improved projection exposure apparatus including such an improved optical module.

A projection lens according to the disclosure of a projection exposure apparatus with an optical module can comprise an optical element and at least one stiffening body, or if desired a plurality of stiffening bodies, wherein the optical element and the stiffening body are connected to one another by at least one connection element. According to the disclosure, the optical element has at least two segments. Segmenting the optical element makes it possible, inter alia, for the individual optical effective surfaces of the segments to be manufactured separately, thus enabling simplified manufacturing.

The segments may for example have a constant thickness in a range of between 5 mm and 60 mm, such as between 10 mm and 40 mm.

The fact that at least one connection element is designed as a mechanical actuator, for example with an effective axis perpendicular to a rear side of the optical element, enables, for example, assembly tolerances to be compensated for and deviations of the optical effective surface of the optical element from its target shape to be compensated for.

It is often desirable for at least one connection element to have two actuators, which are arranged in series and differ in terms of their travel path and their resolution. For example, one of the actuators arranged in series may be designed as a long-stroke actuator. In this case, it can have a travel path in the range of 2 to 10 micrometers and a resolution of 1 to 10 nanometers.

Furthermore, one of the actuators arranged in series may be designed as a short-stroke actuator. It may have a travel path in the range of 10 to 20 nanometers and a resolution of 1 to 10 picometers.

A combination of the long-stroke and short-stroke actuators described above can enable a relatively large actuation path or travel path of the combined actuator created in this manner at the same time as providing relatively high resolution.

The fact that at least one compensation element is arranged between at least one segment and the stiffening body results in further desirable features. For example, in the case of strongly curved optical effective surfaces of the segments, the compensation elements can be used to partially fill the widening gap between the rear side of the segment and the stiffening body on account of the curvature, and thus to make it possible to comply with the maximum thickness of the optical segments. Furthermore, using the compensation elements can enable associated short-stroke and long-stroke actuators to be arranged on opposite sides of the compensation elements, which can, for example, give rise to desirable features during assembly.

For example, at least one long-stroke actuator may be arranged between the stiffening body and the compensation element.

Similarly, at least one short-stroke actuator may be arranged between the compensation element and the at least one segment.

The fact that a plurality of long-stroke actuators are arranged such that the at least one compensation element is mounted on the stiffening body in a statically determinate manner makes it possible to minimize, inter alia, parasitic forces and moments.

If at least one damper is arranged between the compensation element and the stiffening body, relative movements induced by mechanical vibrations can be avoided between the compensation element and the stiffening body, thereby improving the imaging quality of the projection exposure apparatus.

The fact that the segments and/or the compensation elements and/or the stiffening bodies have fluid channels for example makes it possible to cool or control the temperature of the components involved.

The fact that there is at least one lateral decoupling element between the segments, at least one compensation element or at least one stiffening body makes it possible to limit the effects of different coefficients of thermal expansion of the elements involved.

The lateral decoupling element may be designed for example as an actuator or as a flexure.

In a variant of the disclosure, a plurality of short-stroke actuators may be arranged in an edge region of an optical segment with a higher packing density than in a central region. This makes it possible to at least partially compensate for edge effects. Such edge effects should be understood to be, for example, the effect of the material being able to yield laterally on account of the lower rigidity of the material in an edge region of a segment during machining in the course of the production of the segment. After machining, the material then returns to its starting position, so that the edge region may be formed with a surface that deviates from the target shape, for example may be raised. This region would not be available as an optical effective surface without further measures. The higher density of actuators in the edge region makes it possible to compensate for the effects mentioned, and therefore the edge region can also be used as an optical effective surface.

### BRIEF DESCRIPTION OF THE DRAWINGS

Exemplary embodiments and variants of the disclosure are explained in more detail below with reference to the drawings, in which:

FIG. 1 schematically shows a meridional section through a projection exposure apparatus for EUV projection lithography;

FIG. 2 schematically shows a meridional section through a projection exposure apparatus for DUV projection lithography;

FIG. 3 shows a schematic illustration of an optical module according to the disclosure;

FIG. 4 shows a further embodiment of an optical module;

FIGS. 5A, 5B and 5C show a further embodiment of an optical module; and

FIGS. 6A and 6B show an edge of an optical element known from the prior art in order to elucidate a detail of a further embodiment of an optical module.

### DETAILED DESCRIPTION

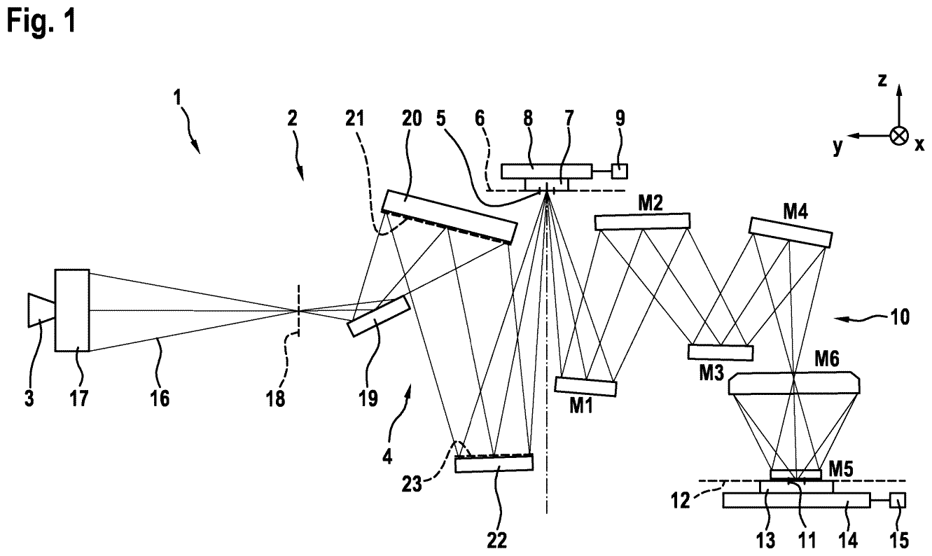

In the following text, certain constituent parts of a microlithographic projection exposure apparatus 1 are described by way of example, initially with reference to FIG. 1. The description of the basic structure of the projection exposure apparatus 1 and the constituent parts thereof are to be understood as non-limiting.

One embodiment of an illumination system 2 of the projection exposure apparatus 1 has, in addition to a radiation source 3, an illumination optics unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable, for example in a scanning direction, by way of a reticle displacement drive 9.

FIG. 1 shows a Cartesian xyz-coordinate system for explanatory purposes. The x-direction runs perpendicularly to the plane of the drawing into the latter. The y-direction runs horizontally, and the z-direction runs vertically. The scanning direction runs along the y-direction in FIG. 1. The z-direction runs perpendicularly to the object plane 6.

The projection exposure apparatus 1 comprises a projection optics unit 10. The projection optics unit 10 is used to image the object field 5 into an image field 11 in an image plane 12. The image plane 12 runs parallel to the object plane 6. Alternatively, a non-0° angle between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable, for example along the y-direction, by way of a wafer displacement drive 15. The displacement, firstly, of the reticle 7 by way of the reticle displacement drive 9 and, secondly, of the wafer 13 by way of the wafer displacement drive 15 may be synchronized with one another.

The radiation source 3 is an EUV radiation source. The radiation source 3 emits for example EUV radiation 16, which is also referred to below as used radiation, illumination radiation or illumination light. The used radiation has for example a wavelength in the range of between 5 nm and 30 nm. The radiation source 3 may be a plasma source, for example an LPP (laser produced plasma) source or a GDPP (gas discharge produced plasma) source. It may also be a synchrotron-based radiation source. The radiation source 3 may be a free electron laser (FEL).

The illumination radiation 16 emanating from the radiation source 3 is focused by a collector 17. The collector 17 may be a collector with one or more ellipsoidal and/or hyperboloidal reflection surfaces. The illumination radiation 16 may be incident on the at least one reflection surface of the collector 17 with grazing incidence (GI), i.e. at angles of incidence of greater than 45° relative to the direction of the normal to the mirror surface, or with normal incidence (NI), i.e. at angles of incidence of less than 45°. The collector 17 may be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may constitute a separation between a radiation source module, comprising the radiation source 3 and the collector 17, and the illumination optics unit 4.

The illumination optics unit 4 comprises a deflection mirror 19 and, arranged downstream thereof in the beam path, a first facet mirror 20. The deflection mirror 19 may be a planar deflection mirror or alternatively a mirror with a beam-influencing effect that goes beyond the pure deflection effect. Alternatively or additionally, the deflection mirror 19 may take the form of a spectral filter that separates a used light wavelength of the illumination radiation 16 from extraneous light having a wavelength that deviates therefrom. If the first facet mirror 20 is arranged in a plane of the illumination optics unit 4 that is optically conjugate to the object plane 6 as a field plane, it is also referred to as a field facet mirror. The first facet mirror 20 comprises a multiplicity of individual first facets 21, which are also referred to below as field facets. FIG. 1 illustrates only some of these facets 21 by way of example.

The first facets 21 may take the form of macroscopic facets, for example rectangular facets or facets with an arcuate edge contour or an edge contour of part of a circle. The first facets 21 may take the form of planar facets or alternatively convexly or concavely curved facets.

As is known from DE 10 2008 009 600 A1, for example, the first facets 21 themselves may each also be composed of a multiplicity of individual mirrors, for example a multiplicity of micromirrors. The first facet mirror 20 may for example take the form of a microelectromechanical system (MEMS system). For details, reference is made to DE 10 2008 009 600 A1.

The illumination radiation 16 travels horizontally, i.e. in the y-direction, between the collector 17 and the deflection mirror 19.

In the beam path of the illumination optics unit 4, a second facet mirror 22 is arranged downstream of the first facet mirror 20. If the second facet mirror 22 is arranged in a pupil plane of the illumination optics unit 4, it is also referred to as a pupil facet mirror. The second facet mirror 22 may also be spaced apart from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 may also be macroscopic facets, which may for example have a round, rectangular or hexagonal boundary, or may alternatively be facets composed of micromirrors. In this regard, reference is likewise made to DE 10 2008 009 600 A1.

The second facets 23 may have planar or alternatively convexly or concavely curved reflection surfaces.

The illumination optics unit 4 thus forms a doubly faceted system. This fundamental principle is also referred to as a fly's eye integrator.

It may be desirable to arrange the second facet mirror 22 not exactly in a plane that is optically conjugate to a pupil plane of the projection optics unit 10. For example, the pupil facet mirror 22 may be arranged so as to be tilted relative to a pupil plane of the projection optics unit 10, as described for example in DE 10 2017 220 586 A1.

The second facet mirror 22 is used to image the individual first facets 21 into the object field 5. The second facet mirror 22 is the last beam-shaping mirror or actually the last mirror for the illumination radiation 16 in the beam path upstream of the object field 5.

In a further embodiment (not illustrated) of the illumination optics unit 4, a transfer optics unit contributing for example to the imaging of the first facets 21 into the object field 5 may be arranged in the beam path between the second facet mirror 22 and the object field 5. The transfer optics unit may comprise exactly one mirror, or alternatively two or more mirrors arranged one behind another in the beam path of the illumination optics unit 4. The transfer optics unit may for example comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the field facet mirror 20 and the pupil facet mirror 22.

In a further embodiment of the illumination optics unit 4, the deflection mirror 19 may also be omitted, and so the illumination optics unit 4 may have exactly two mirrors downstream of the collector 17 in that case, specifically the first facet mirror 20 and the second facet mirror 22.

The imaging of the first facets 21 into the object plane 6 via the second facets 23, or using the second facets 23 and a transfer optics unit is generally only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or any other number of mirrors Mi are also possible. The penultimate mirror M5 and the last mirror M6 each have a passage opening for the illumination radiation 16. The projection optics unit 10 is a doubly obscured optics unit. The projection optics unit 10 has an image-side numerical aperture that is greater than 0.5 and may also be greater than 0.6 and may be, for example, 0.7 or 0.75.

Reflection surfaces of the mirrors Mi may take the form of free-form surfaces without an axis of rotational symmetry. Alternatively, the reflection surfaces of the mirrors Mi may be designed as aspherical surfaces with exactly one axis of rotational symmetry of the reflection surface shape. Just like the mirrors of the illumination optics unit 4, the mirrors Mi may have highly reflective coatings for the illumination radiation 16. These coatings can be designed as multilayer coatings, for example with alternating layers of molybdenum and silicon.

The projection optics unit 10 has a large object-image shift in the y-direction between a y-coordinate of a center of the object field 5 and a y-coordinate of the center of the image field 11. This object-image shift in the y-direction may have approximately the same magnitude as a z-distance between the object plane 6 and the image plane 12.

For example, the projection optics unit 10 may have an anamorphic design. For example, it has different imaging scales βx, βy in the x-and y-directions. The two imaging scales βx, βy of the projection optics unit 10 can be (βx, βy)=(+/−0.25, +/−0.125). A positive imaging scale β means imaging without image inversion. A negative sign for the imaging scale β means imaging with image inversion.

The projection optics unit 10 thus leads to a reduction in size with a ratio of 4:1 in the x-direction, i.e. in a direction perpendicular to the scanning direction.

The projection optics unit 10 leads to a reduction in size of 8:1 in the y-direction, i.e. in the scanning direction.

Other imaging scales are likewise possible. Imaging scales with the same signs and the same absolute values in the x-and y-directions, for example with absolute values of 0.125 or 0.25, are also possible.

The number of intermediate image planes in the x-direction and in the y-direction in the beam path between the object field 5 and the image field 11 may be the same or may be different, depending on the embodiment of the projection optics unit 10. Examples of projection optics units with different numbers of such intermediate images in the x-and y-directions are known from US 2018/0074303 A1.

In each case, one of the pupil facets 23 is assigned to exactly one of the field facets 21 for the purpose of forming a respective illumination channel for illuminating the object field 5. For example, this may result in illumination according to the Köhler principle. The far field is decomposed into a multiplicity of object fields 5 with the aid of the field facets 21. The field facets 21 generate a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is for example as homogeneous as possible. It can have a uniformity error of less than 2%. Field uniformity can be achieved by overlaying different illumination channels.

The illumination of the entrance pupil of the projection optics unit 10 may be defined geometrically by way of an arrangement of the pupil facets. The intensity distribution in the entrance pupil of the projection optics unit 10 may be set by selecting the illumination channels, for example the subset of the pupil facets that guide light. This intensity distribution is also referred to as illumination setting.

A likewise preferred pupil uniformity in the region of portions of an illumination pupil of the illumination optics unit 4 that are illuminated in a defined manner may be achieved by a redistribution of the illumination channels.

Further aspects and details of the illumination of the object field 5 and for example of the entrance pupil of the projection optics unit 10 are described below.

The projection optics unit 10 may have for example a homocentric entrance pupil. The latter may be accessible. It may also be inaccessible.

The entrance pupil of the projection optics unit 10 cannot, as a rule, be exactly illuminated using the pupil facet mirror 22. The aperture rays often do not intersect at a single point in the event of imaging by the projection optics unit 10 that telecentrically images the center of the pupil facet mirror 22 onto the wafer 13. However, it is possible to find an area in which the spacing of the aperture rays, which is determined in pairs, becomes minimal. This area represents the entrance pupil or an area conjugate thereto in real space. For example, this area exhibits a finite curvature.

It may be the case that the projection optics unit 10 has different poses of the entrance pupil for the tangential beam path and for the sagittal beam path. In this case, an imaging element, for example an optical component of the transfer optics unit, should be provided between the second facet mirror 22 and the reticle 7. This optical element may be used to take into account the different poses of the tangential entrance pupil and the sagittal entrance pupil.

In the arrangement of the components of the illumination optics unit 4 illustrated in FIG. 1, the pupil facet mirror 22 is arranged in an area conjugate to the entrance pupil of the projection optics unit 10. The field facet mirror 20 is arranged so as to be tilted with respect to the object plane 6. The first facet mirror 20 is arranged so as to be tilted with respect to an arrangement plane defined by the deflection mirror 19.

The first facet mirror 20 is arranged so as to be tilted with respect to an arrangement plane defined by the second facet mirror 22.

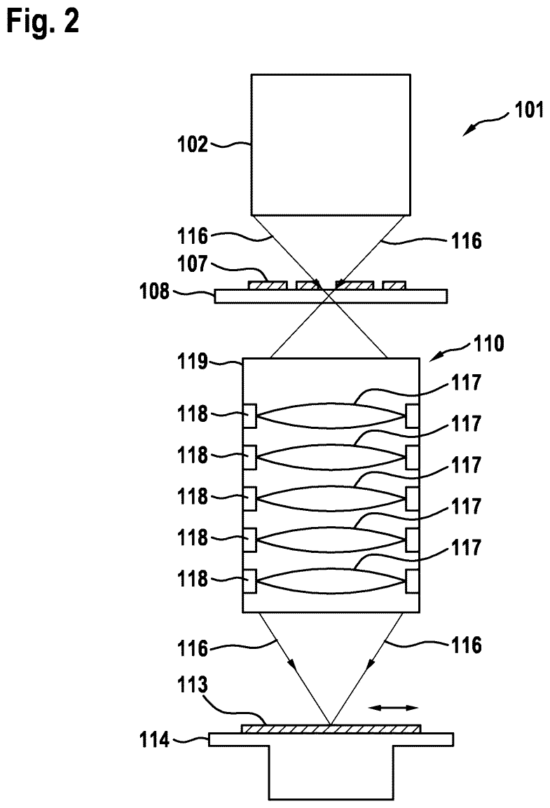

FIG. 2 schematically shows a meridional section through a further projection exposure apparatus 101 for DUV projection lithography, in which the disclosure can likewise be used.

The structure of the projection exposure apparatus 101 and the principle of the imaging are comparable with the structure and procedure described in FIG. 1. Identical components are denoted by a reference sign increased by 100 relative to FIG. 1, i.e. the reference signs in FIG. 2 start at 101.

By contrast to an EUV projection exposure apparatus 1 as described in FIG. 1, refractive, diffractive and/or reflective optical elements 117, such as lens elements, mirrors, prisms, terminating plates, and the like, can be used for imaging or for illumination in the DUV projection exposure apparatus 101 on account of the greater wavelength of the DUV radiation 116, employed as used light, in the range from 100 nm to 300 nm, for example of 193 nm. The projection exposure apparatus 101 in this case substantially comprises an illumination system 102, a reticle holder 108 for receiving and exactly positioning a reticle 107, which is provided with a structure and is used to determine the later structures on a wafer 113, a wafer holder 114 for holding, moving, and exactly positioning this very wafer 113, and a projection lens 110, with a plurality of optical elements 117 held by way of mounts 118 in a lens housing 119 of the projection lens 110.

The illumination system 102 provides DUV radiation 116 for the imaging of the reticle 107 on the wafer 113. A laser, a plasma source or the like may be used as the source of this radiation 116. The radiation 116 is shaped in the illumination system 102 using optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the structure of the downstream projection optics unit 101 with the lens housing 119 does not differ in principle from the structure described in FIG. 1 and is therefore not described in further detail.

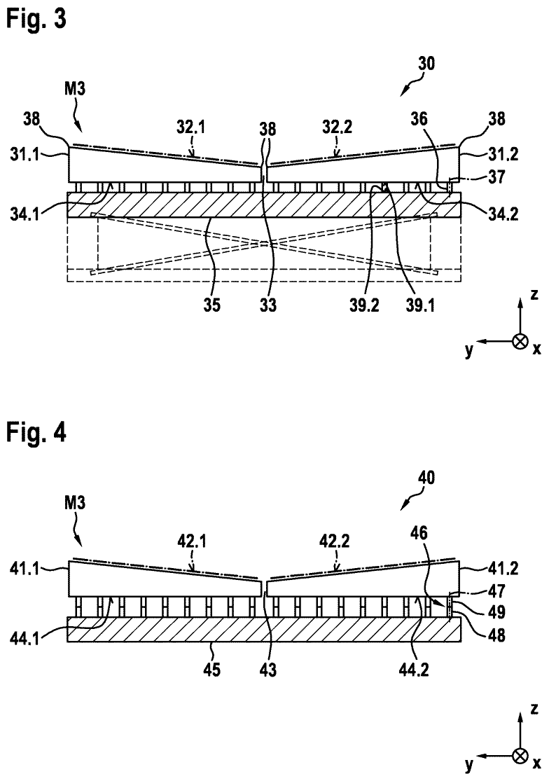

FIG. 3 shows a schematic illustration of an optical module according to the disclosure designed as a mirror module 30, which in the example shown comprises an optical element formed as a mirror M3 from the projection exposure apparatus 1 explained in FIG. 1. In the example shown, the mirror M3 comprises four segments, but just two segments 31.1, 31.2 are illustrated on account of the selected section between the segments in the sectional illustration in FIG. 3. These each comprise an optical effective surface 32.1, 32.2, on which used light is incident during operation of the projection exposure apparatus 1 in order to image a structure of a reticle 7 (FIG. 1) and which is illustrated in FIG. 3 as a dash-dotted line. For manufacturing reasons, the optical effective surfaces 32.1, 32.2 are not formed up to the edges 38 of the segments 31.1, 31.2.

Forming the mirror M3 in segments 31.1, 31.2 means that the individual optical effective surfaces 32.1, 32.2 are smaller relative to the total surface area of the mirror M3, thus enabling them to be produced in a simple manner. This has a positive influence on the production costs. A gap 33 is inherently formed between the segments 31.1, 31.2, but this has no significant influence on the imaging quality of the projection exposure apparatus 1.

The mirror module 30 further comprises a stiffening body 35, which is arranged on the rear sides 34.1, 34.2, which are on the opposite side to the optical effective surfaces 32.1, 32.2, of the segments 31.1, 31.2 and is connected to the segments 31.1, 31.2 via connection elements designed as actuators 36. In conjunction with the actuators 36, the stiffening body 35 stiffens the segments 31.1, 31.2, for example in the z-direction oriented perpendicular to the rear sides 34.1, 34.2 in the example, thus making it possible for the segments to be selected with a smaller thickness compared to previous mirrors with the same radius.

The stiffness of the mirror module 30 in the lateral x-y plane perpendicular to the z-direction is fundamentally less critical, and therefore the solution shown in the figure by way of example also has a sufficiently high lateral stiffness of the mirror module 30 including the connection elements 36 and the stiffening body 35.

The stiffening body 35 can be made from the same material as the segments 31.1, 31.2, which means that the components 31.1, 31.2, 35 have the same coefficient of thermal expansion. Thus, with uniform heating of the components 31.1, 31.2, 35, lateral (x-y-direction) displacements of different sizes of the attachment points 39.1, 39.2 of the actuators 36 on the segments 31.1, 31.2 or the stiffening body 35 are reduced or even completely avoided. An introduction of forces and moments caused by the displacements on the rear sides 34.1, 34.2 of the segments 31.1, 31.2 and the resulting possible deformation of the optical effective surfaces 32.1, 32.2 is avoided. In order to provide further stiffening and to reduce the mass and thickness thereof, the stiffening body 35 may also be formed as a lightweight structure, which is indicated in FIG. 3 by a lattice structure illustrated using dashed lines.

Alternatively, the stiffening body 35 may comprise a different material than the mirror material, such as a ceramic, for example silicon carbide, which has a Young's modulus that is higher than that of the mirror material at least by a factor of 2, such as at least by a factor of 3, for example by a factor of 4. This makes it possible for the mirror module 30 to be realized with virtually no change in overall stiffness with significantly lower material use, this having a positive effect on the installation space as well as the total mass and, on account of the lower material, also on the cost of producing the mirror module 30.

The effective axes 37 of the actuators 36 are oriented perpendicular to the rear sides 34.1, 34.2 of the mirror M3 in the z-direction. The actuators 36 are used, inter alia, to compensate for manufacturing and/or assembly tolerances of the stiffening body 35 and the segments 31.1, 31.2. Furthermore, the actuators 36 can deform the optical segments 31.1, 31 2, thus making it possible to correct deviations from their target shape of the optical effective surfaces 32.1, 32.2 relevant for the imaging. In order to minimize the forces to deform the segments 31.1, 31.2, the thickness of the segments 31.1, 31.2 is limited to a range of between 10 mm and 40 mm.

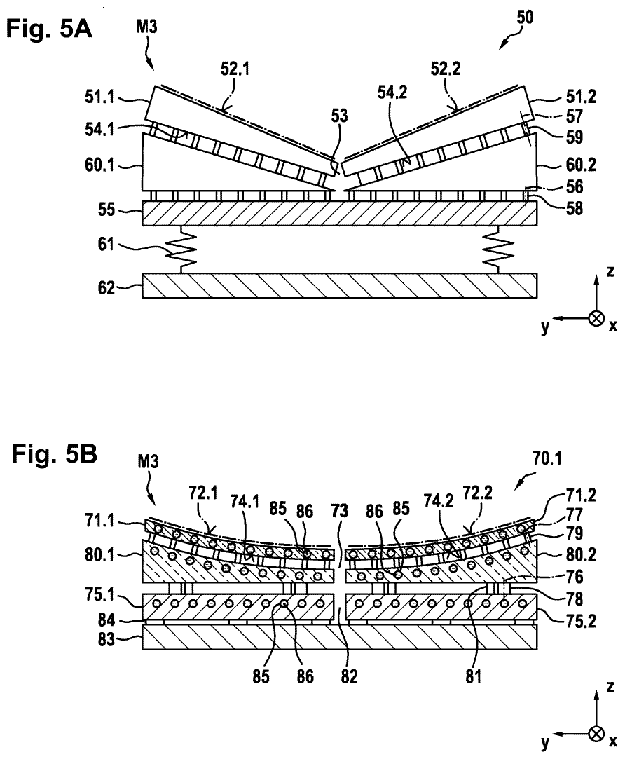

FIG. 4 shows a further embodiment of an optical module, which is illustrated in a sectional illustration and designed as a mirror module 40, with an optical element designed as a mirror M3. The structure of the mirror module 40 is similar to the mirror module 30 explained in FIG. 3, with identical elements being denoted, where appropriate, by reference signs that have been increased by 10 in relation to the designation in FIG. 3.

The connection elements 46 each have two actuators 48, 49, which are arranged in series. These differ in terms of their travel path and their resolution, wherein the so-called long-stroke actuator 48 illustrated at the bottom of the figure has a comparatively long travel path and a low resolution and the upper, so-called short-stroke actuator 49 has a short travel path and a high resolution. In the case of actuators, especially piezoelectric actuators, the ratio of travel path to resolution depends predominantly on the resolution of the control electronics used, which can usually reach a resolution in the range of a ten thousandth to a hundred thousandth. The total travel can be for example between 2 nm and 20 μm, wherein the long-stroke actuator 48 can travel at least twice, such as five times, for example 10 times, especially more than 100 times, as far as the short-stroke actuator 49.

The long-stroke actuator 48 can have a maximum travel path in the range of 2 to 10 micrometers and can be configured, in combination with the control electronics, to achieve an accuracy in the range of 1 to 10 nanometers.

The resolution of the long-stroke actuator can be 0.01 to 1 nanometer, such as 0.01 to 0.1 nanometers. The short-stroke actuator 49 can have a travel path in the range of 10 to 20 nanometers and a resolution of 1 to 10 picometers. The travel path of the short-stroke actuator 49 is greater than or equal to the resolution of the long-stroke actuator 48. The combination of a long-stroke actuator 48 and a short-stroke actuator 49 thus enables a long travel path at the same time as high resolution.

The long-stroke actuator 48 is predominantly used for correcting assembly tolerances and manufacturing tolerances, which are dependent on the material used, for example for the stiffening body 45, and the manufacturing technologies applied and can be in the range of 2 to 10 micrometers. Furthermore, the long-stroke actuator 48 is applied in order to correct possible changes in the spacing between the stiffening body 45 and the segments 41.1, 41.2 during operation. The spacing may be caused, for example, by settling effects and/or drifting effects on account of the connection technologies, such as for example (adhesive) bonding, applied between the components 41.1, 41.2, 45, 48, 49, as well as thermal effects on account of gradual heating of the mirror module 40 during operation of the projection exposure apparatus 1.

The short-stroke actuator 49 is predominantly used for correcting parasitic deformations of the optical effective surfaces 42.1, 42.2, which can be caused by forces and moments acting on the segments 32.1, 32.2. Furthermore, the imaging quality of the projection exposure apparatus 1 can be improved by predetermined deformation of the optical effective surfaces 42.1, 42.2. This can also be used to correct imaging aberrations caused by other optical elements or components of the projection exposure apparatus.

In principle, a wide variety of actuators can be used as long-stroke and short-stroke actuators. Both primarily force-generating actuators such as Lorentz actuators and mainly displacement-generating actuators such as solid-state actuators can be used.

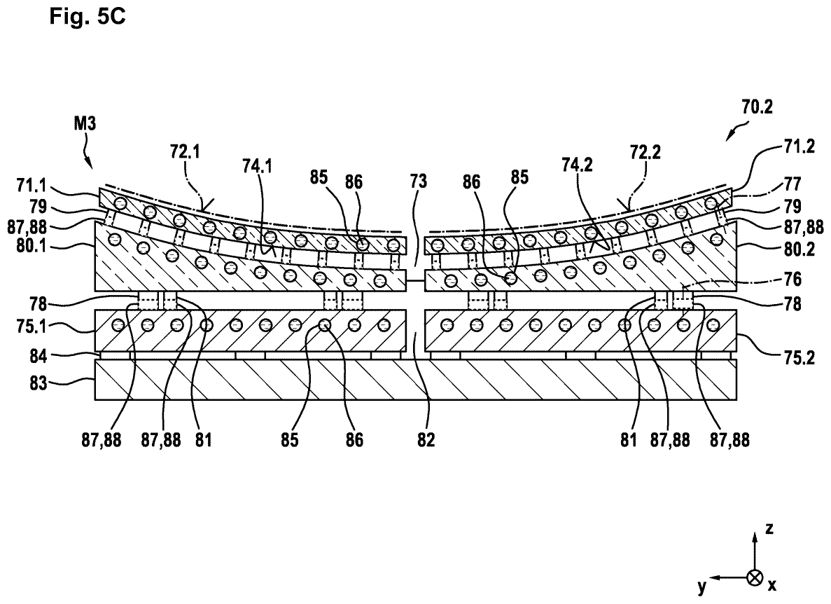

On account of their inherent rigidity, solid-state actuators are desirable for stiffening the segments 41.1, 41.2. Closed-loop control is usually used in the case of force actuator systems. In this case, however, the low lateral stiffnesses of the force actuators are desirable, for example with regard to compensating for different thermal expansions. These can act as lateral decoupling elements, as will be explained in even more detail in FIG. 5C.

The solid-state actuator system can be realized, for example, by piezoelectric and/or electrostrictive actuators. Multi-axiality can be achieved by combining a plurality of single-axis actuators. These can be designed as an actuator unit with a plurality of control lines or can be produced from individual actuators by joining processes.

Similarly, multi-axiality can be achieved by the applied field acting in different directions.

Furthermore, the solid-state actuator system can be realized using the photostrictive, magnetostrictive or thermostrictive effect or a combination of the effects.

In an embodiment, a combination of a plurality of separately controllable piezo regions is used, wherein transverse piezo actuators can be combined with shear piezo actuators.

Both the long-stroke actuator 48 and the short-stroke actuator 49 may also be designed as a multi-axis actuator.

If an actuator 48, 49 has a lateral degree of freedom, i.e. an actuator that can be controlled in the x-y plane, this can be used as a lateral decoupling element, as explained in FIG. 5C.

FIG. 5A shows a further embodiment of an optical module, which is illustrated in a sectional illustration and designed as a mirror module 50, with an optical element designed as a mirror M3. The basic structure of the mirror module 50 is identical to the mirror module 40 explained in FIG. 4, with identical elements being denoted, as appropriate, by reference signs that have been increased by 10 in relation to the designation in FIG. 4. The strongly concave shape of the mirror M3 illustrated in the embodiment and the limitation of the maximum thickness of the optical segments 51.1, 51.2 explained above result in the mirror module 50 having additional compensation elements 60.1, 60.2 between the segments 51.1, 51.2 and the stiffening body 55 compared to the mirror module 40 of FIG. 4. These compensate for the remaining spacing between the rear sides 54.1, 54.2 of the segments 51.1, 51.2 and the stiffening body 55 arranged parallel to the x-y plane and thus make it possible to comply with the maximum thickness of the optical segments 51.1, 51.2. The additional compensation elements 60.1, 60.2 mean that the long-stroke actuator 58 and the short-stroke actuator 59 do not have to be directly connected to one another, as a result of which assembly is simplified.

In the example shown in the figure, the long-stroke actuators 58 with their effective axes 56 are arranged between the stiffening body 55 and the compensation elements 60.1, 60.2 and compensate, as explained above, for assembly and manufacturing tolerances. In this case, the compensation elements 60.1, 60.2 are not deformed in a targeted manner by the long-stroke actuators 58, but are moved virtually as a rigid body. This means that the thickness of the compensation elements 60.1, 60.2 is not limited.

The short-stroke actuators 59 with their effective axes 57 are arranged between the compensation elements 60.1, 60.2 and the segments 51.1, 51.2 and deform the optical effective surfaces 52.1, 52.2 such that they correspond to the predetermined target shapes.

The embodiment of the mirror module 50 illustrated in FIG. 5A further comprises actuators 61 for positioning the mirror module 50 in up to six degrees of freedom. The actuators 61 are supported on a module support frame 62. Arranging the mirror module 50 on a module support frame 62 enables the mirror module 50 to be more easily handled and tested or calibrated as an autonomous module. This is desirable firstly in terms of assembly and manufacturing and secondly in the case of a possible replacement of a mirror module in the field, for example in the case of a modular design of the projection exposure apparatuses 1. In this case, the optical effective surfaces 52.1, 52.2 can be oriented with respect to a reference (not illustrated) on the module support frame 62. The reference is in turn oriented with respect to a central support frame of the projection exposure apparatuses 1, as a result of which the M3 mirror, after replacement, is positioned virtually in the same position as the replaced mirror.

FIG. 5B shows a further embodiment of an optical module, which is illustrated in a sectional illustration and designed as a mirror module 70.1, with an optical element designed as a mirror M3, wherein the section in this embodiment passes through the two visible segments 71.1, 71.2 of the mirror M3. The structure of the mirror module 70.1 is similar to the mirror module 50 explained in FIG. 5A, with identical elements being denoted, as appropriate, by reference signs that have been increased by 20 in relation to the designation in FIG. 5A. In contrast to the mirror module 50 explained in FIG. 5A, the optical segments 71.1, 71.2 of the mirror module 70.1 are formed with a constant thickness. This means that the forces to be applied by the short-stroke actuators 79 across the segments 71.1, 71.2 in order to deform the segments 71.1, 71.2 are of approximately the same magnitude, as a result of which the parasitic forces and moments acting on the segments 71.1, 71.2 can be minimized.

Furthermore, the mirror module 70.1 has two stiffening bodies 75.1, 75.2. The stiffening bodies 75.1, 75.2 are positioned on the module support frame 83 and oriented with respect to one another via spacer elements, so-called spacers 84, produced with a predetermined thickness. Alternatively, the spacers 84 can be replaced by actuators (not illustrated) for positioning the stiffening bodies 75.1, 75.2 on the module support frame 83.

In the embodiment illustrated in FIG. 5B, the long-stroke actuators 78 are arranged such that the compensation elements 80.1, 80.2 are mounted on the stiffening bodies 75.1, 75.2 in a statically determinate manner. The statically determinate mounting means that the parasitic forces and moments acting on the compensation elements 80.1, 80.2 can be minimized. Furthermore, machining just three individual attachment points for the long-stroke actuators 78 is easier than machining a multiplicity of attachment points, as in the embodiment explained in FIG. 5A with a multiplicity of long-stroke actuators 58, this having a positive effect on the cost of producing the stiffening bodies 75.1, 75.2 and, on account of the reduced number of long-stroke actuators 78, on the cost of producing the mirror module 70.1 as well. Furthermore, this makes it possible to reduce the travel path of the long-stroke actuators 78, as a result of which they have a higher resolution, as explained above.

In the embodiment illustrated in FIG. 5B, in addition to the long-stroke actuators 78, dampers 81 are arranged between the compensation elements 80.1, 80.2 and the stiffening bodies 75.1, 75.2. These dampers are used to damp possible relative movements induced by mechanical vibrations between the compensation elements 80.1, 80.2 and the stiffening bodies 75.1, 75.2, this having a positive effect on the imaging quality of the projection exposure apparatus 1.

Furthermore, in the example shown, the segments 71.1, 71.2, the compensation elements 80.1, 80.2 and the stiffening bodies 75.1, 75.2 have fluid channels 85, through which a fluid 86, for example in the form of water, flows in order to cool the components 71.1, 71.2, 75.1, 75.2, 80.1, 80.2. This is desirable if the stiffening bodies 75.1, 75.2 are formed from a material that is different than the optical material of the segments 71.1, 71.2. The cooling minimizes the displacement of the attachment points of the actuators 78, 79 by the different expansions of the components 71.1, 71.2, 75.1, 75.2, 80.1, 80.2 caused by different coefficients of thermal expansion of the materials. Ideally, this makes it possible to dispense with lateral decoupling between the components 71.1, 71.2, 75.1, 75.2, 80.1, 80.2. If lateral decoupling becomes desirable, this can be realized actively, for example in the form of actuators acting in the x-direction and in the y-direction or passively, for example in the form of flexures or a combination of active and passive decoupling. The actuators and/or flexures may be formed as part of the long-stroke actuators 78 and/or the short-stroke actuators 79.

FIG. 5C shows a further embodiment of an optical module, which is illustrated in a sectional illustration and designed as a mirror module 70.2, with an optical element designed as a mirror M3, wherein the section in this embodiment passes through the two visible segments 71.1, 71.2 of the mirror M3. The structure of the mirror module 70.2 is similar to the mirror module 70.1 explained in FIG. 5B, with identical elements being denoted, as appropriate, by identical reference signs. In contrast to the mirror module 70.1 explained in FIG. 5B, lateral decoupling elements designed as actuators 87 or flexures 88 are arranged between the segments 71.1, 71.2 and the compensation elements 80.1, 80.2 and/or between the compensation elements 80.1, 80.2 and the stiffening bodies 75.1, 75.2, which is why the decoupling elements 87, 88 in FIG. 5C are illustrated by dashed lines. The lateral decoupling elements 87, 88 limit the effects of different coefficients of thermal expansion of the elements 71.1, 71.2, 75.1, 75.2, 80.1, 80.2 involved.

The actuators 87 can be designed as independent actuators or as part of the short-stroke actuators 79 or long-stroke actuators 78. A corresponding configuration of a multi-axis solid state actuator 48, 49 is explained in FIG. 4. In this case, the multi-axis solid-state actuator 48, 49, 78, 79 has a controllable lateral degree of freedom.

Alternatively, if force actuators 48, 49 are used, for example a Lorentz actuator, as explained in FIG. 4, a design-related low lateral stiffness can act as a lateral decoupling element, for example with regard to the compensation of different thermal expansions.

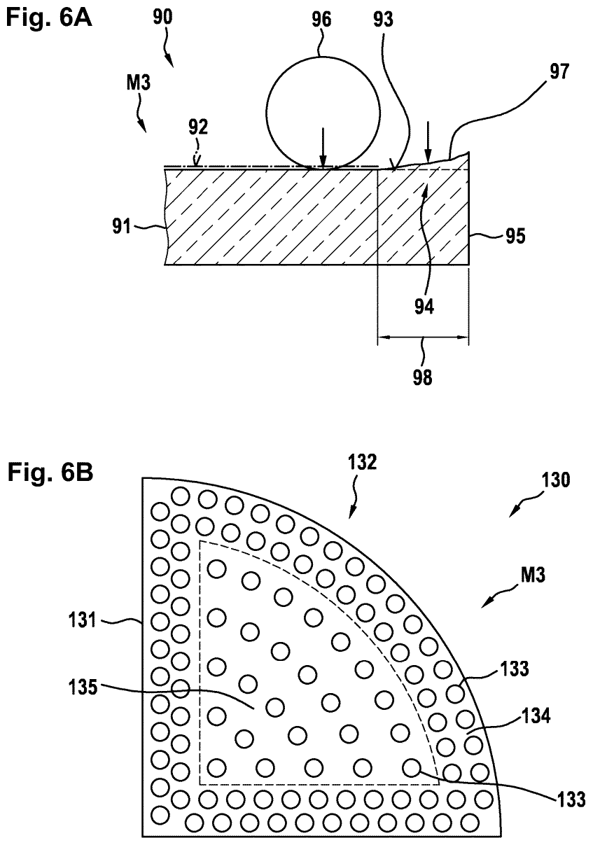

FIG. 6A shows a schematic illustration for explaining a machining process known from the prior art for one of the mirrors shown of an optical module 90. In order to produce the surface 93 comprising the optical effective surface 92 of an optical segment 91 of the mirror M3 explained in the preceding figures, the surface 93 is machined using a tool 96. On account of the laterally (x-y-direction) missing material at the edge 95, which has a supporting effect and thus an influence on the stiffness in the z-direction perpendicular to the optical effective surface 92, the stiffness in the edge region 94 is lower and the material can yield during machining. After machining and thus after the vertical pressure has been removed, the edge region 94 returns to its original shape, thus resulting in the unevennesses in the edge region 94 illustrated in FIG. 6. On account of these unevennesses 97, the optical effective surface 92 indicated in FIG. 6A by a dash-dotted line cannot be formed up to the edge 95, and therefore a region 98 at the edge 95 remains unused for the imaging.

FIG. 6B shows an arrangement according to the disclosure of short-stroke actuators 133 on the rear side 132 of an optical segment 131 for compensating for the unevennesses 97 (not visible in FIG. 6B) caused by the machining in the edge region 134 of the mirror M3. The short-stroke actuators 133, which are explained in FIG. 5A, inter alia, are arranged in the edge region 134 with a higher packing density than in the central region 135. The high packing density results in a higher resolution in the correction of deformations on the surface 93 (FIG. 6A), which is not visible in FIG. 6B. The high resolution enables the predominantly short-wave unevennesses 97 (FIG. 6A) to be corrected, as a result of which the optical effective surface can be implemented up to the edge 95 (FIG. 6A).

In the central region 135, in which predominantly long-wave deformations caused, for example, by natural frequencies or thermal effects, have to be corrected, a lower packing density is sufficient.

The arrangement according to the disclosure of the short-stroke actuators 133 can enable the optical effective surface 93 to be formed up to the edge 95 (FIG. 6A). This leads to desirable minimization of the unused region 98 (FIG. 6A) of the individual optical segments 72.1, 72.2 (FIG. 5B), and therefore the region of the mirror M3 not used for imaging at the above-explained gap 73 (FIG. 5B) between the individual segments 71.1, 71.2 (FIG. 5B) can be reduced, as a result of which imaging quality is improved. The optical effective surface 92 (FIG. 6A) up to the edge 95 (FIG. 6A) can provide a positive effect on the production costs on account of the reduced material use for the optical module 90.

The arrangement of the short-stroke actuators 133 illustrated in FIG. 6B can be used in all of the above-explained embodiments and can also be used for utilizing the edge region of one-piece mirrors.

### List of reference signs

1 Projection exposure apparatus
2 Illumination system
3 Radiation source
4 Illumination optics unit
5 Object field
6 Object plane
7 Reticle
8 Reticle holder
9 Reticle displacement drive
10 Projection optics unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Optical module
31.1, 31.2 Mirror segment
32.1, 32.2 Optical effective surface
33 Gap
34.1, 34.2 Rear side of segments
35 Stiffening body
36 Actuator
37 Effective axis
38 Edge
39.1, 39.2 Attachment points
40 Optical module
41.1, 41.2 Mirror segment
42.1, 42.2 Optical effective surface
43 Gap
44.1, 44.2 Rear side of segments
45 Stiffening body
46 Connection element
47 Effective axis
48 Long-stroke actuator
49 Short-stroke actuator
50 Optical module
51.1, 51.2 Optical element segment
52.1, 52.2 Optical effective surface
53 Gap
54.1, 54.2 Rear side of segments
55 Stiffening body
56 Effective axis
57 Effective axis
58 Long-stroke actuator
59 Short-stroke actuator
60.1, 60.2 Compensation element
61 Actuator
62 Module support frame
70.1, 70.2 Optical module
71.1, 71.2 Mirror segment
72.1, 72.2 Optical effective surface
73 Gap
74.1, 74.2 Rear side of segments
75.1, 75.2 Stiffening body
76 Effective axis
77 Effective axis
78 Long-stroke actuator
79 Short-stroke actuator
80.1, 80.2 Actuator
81 Damper
82 Stiffening segment body gap
83 Support structure
84 Spacer
85 Fluid channel
86 Fluid
87 Laterally acting actuator
88 Laterally decoupling flexure
90 Optical module
91 Segment
92 Optical effective surface
93 Surface
94 Edge region
95 Edge
96 Tool
97 Unevenness
98 Unused region of the optical segment
101 Projection exposure apparatus
102 Illumination system
107 Reticle
108 Reticle holder
110 Projection optics unit
113 Wafer
114 Wafer holder
116 DUV radiation
117 Optical element
118 Mounts
119 Lens housing
130 Optical module
131 Optical segment
132 Rear side of segment
133 Actuators
134 Edge region
135 Central region

What is claimed is:

1. A projection lens, comprising:
an optical module, comprising:
an optical element comprising a first segment and a second segment;
a stiffening body;
a connection element connecting the optical element and the stiffening body; and
a lateral decoupling element between the first segment and the stiffening body.

2. The projection lens of claim 1, wherein the connection element comprises a mechanical actuator.

3. The projection lens of claim 2, wherein an effective axis of the mechanical actuator is perpendicular to a rear side of the optical element.

4. The projection lens of claim 1, wherein the connection element comprises first and second actuators configured in series, the first actuator has a travel path that is different from a travel path of the second actuator, and the first actuator has a resolution that is different from a resolution of the second actuator.

5. The projection lens of claim 4, wherein the first actuator has a travel path of from two micrometers to 10 micrometers, and the first actuator has a resolution of from one nanometer to 10 nanometers.

6. The projection lens of claim 5, wherein the second actuator has a travel path of from 10 nanometers to 20 nanometers, and the second actuator has a resolution of from one picometer to 10 picometers.

7. The projection lens of claim 1, wherein:
the first and second segments comprises fluid channels; and/or the stiffening body comprises fluid channels.

8. The projection lens of claim 1, wherein the lateral decoupling element comprises an actuator or a flexure.

9. The projection lens of claim 8, comprising a plurality of actuators are arranged in an edge region of the first segment, wherein the first segment has a higher packing density in the edge region than in a central region of the first segment, and each of the plurality of actuators has a travel path of from 10 nanometers to 20 nanometers and a resolution of from one picometer to 10 picometers.

10. The projection lens of claim 1, wherein comprising a plurality of stiffening bodies.

11. The projection lens of claim 1, further comprising a second lateral decoupling element, wherein the second lateral decoupling element is between the second segment and the stiffening body.

12. An apparatus, comprising:
the projection lens of claim 1,
wherein the apparatus is a semiconductor lithography projection exposure apparatus.

13. A projection lens, comprising:
an optical module, comprising:
an optical element comprising a first segment and a second segment;
first and second stiffening bodies;
first and second connection elements,
wherein the first connection element connects the first segment to the first stiffening body, and the second connection element connects the second segment to the second stiffening body.

14. An apparatus, comprising:
the projection lens of claim 13,
wherein the apparatus is a semiconductor lithography projection exposure apparatus.

15. A projection lens, comprising:
an optical module, comprising:
an optical element comprising a first segment and a second segment;
a stiffening body;
a compensation element between the optical element and the stiffening body;
a first connection element connecting the compensation element and the stiffening body; and
a second connection element connecting the compensation element and the first segment.

16. The projection lens of claim 15, wherein the first connection element comprises a first actuator, wherein the first actuator has a travel path of from two micrometers to 10 micrometers and a resolution of from one nanometer to 10 nanometers.

17. The projection lens of claim 16, wherein the second connection element comprises a second actuator, wherein the second actuator has a travel path of from 10 nanometers to 20 nanometers and a resolution of from one picometer to 10 picometers.

18. The projection lens of claim 15, wherein the first connection element comprises a plurality of actuators, wherein at least one of the plurality of actuators is mounted on the stiffening body in a statically determinate manner, and each of the plurality of actuators has a travel path of from two micrometers to 10 micrometers and a resolution of from one nanometer to 10 nanometers.

19. The projection lens of claim 15, further comprising a damper between the compensation element and the stiffening body.

20. An apparatus, comprising:
the projection lens of claim 15,
wherein the apparatus is a semiconductor lithography projection exposure apparatus.
